(19) United States
(12) Patent Application Publication
(10) Pub. No.: US 2026/0181319 A1
(43) Pub. Date: Jun. 25, 2026

(54) CONTROL CIRCUIT FOR A MICROELECTROMECHANICAL SOUND GENERATOR, AND SOUND GENERATION SYSTEM

(71) Applicant: Robert Bosch GmbH, Stuttgart (DE)

(72) Inventor: Guido De Sandre, Brugherio (IT)

(21) Appl. No.: 18/855,035

(22) PCT Filed: May 3, 2023
(86) PCT No.: PCT/EP2023/061707

§ 371 Date: Oct. 8, 2024

(30) Foreign Application Priority Data
May 30, 2022 (DE) 10 2022 205 384.2

(51) Int. Cl. H04R 3/00; H03F 1/02; H03F 3/45; H04R 1/00

(52) U.S. Cl. CPC H04R 3/00; H03F 1/0227; H04R 1/00; H03F 3/45475; H03F 2200/03; H04R 2201/003

(57) ABSTRACT

Control of an electrostatic sound transducer including a microelectronic component. A control circuit including a differential amplifier is provided, wherein, at a central terminal of the sound transducer, a bias voltage is provided relative to the common mode voltage of the differential amplifier. The supply voltage of the differential amplifier is adjusted on the basis of the maximum signal amplitude of the input signal.

### FIELD

The present invention relates to a control circuit for a microelectromechanical sound generator and to a sound generation system comprising such a control circuit. In particular, the present invention relates to the control of a microelectromechanical sound generator comprising an electrostatically controllable membrane.

### BACKGROUND INFORMATION

Sound generators can be used in loudspeakers, earphones or similar to generate sound waves from an electrical signal. As miniaturization progresses, sound generation elements based on microelectromechanical systems (MEMS) are also becoming increasingly important. For example, there are sound generators in which a membrane can be excited by means of electrostatic forces.

European Patent Application No. EP 2582156 A2, for example, describes an electrostatic loudspeaker that can be designed as a microelectromechanical system.

### SUMMARY

The present invention provides a control circuit for a microelectromechanical sound generator and a sound generation system. Advantageous example embodiments of the present invention are disclosed herein.

According to an example embodiment of the present invention, a control circuit for a microelectromechanical sound generator is provided. The sound generator can have two outer terminals and one central terminal. The control circuit comprises a differential amplifier and a voltage generator circuit. The differential amplifier comprises two output terminals. Each of the two output terminals is electrically coupled to a corresponding output terminal of the sound generator. The differential amplifier is designed to provide, between the two output terminals, an output voltage that corresponds to an input signal between two input terminals of the differential amplifier. The voltage generator circuit is designed to provide, at the central terminal of the sound generator, a predetermined, preferably constant DC voltage relative to a common mode voltage of the differential amplifier. In particular, the control circuit is designed to set a supply voltage for the differential amplifier on the basis of a maximum amplitude of the input signal.

Furthermore, an example embodiment of the present invention provides:

A sound generation system comprising a microelectromechanical sound generator and a control circuit according to the present invention. The sound generator comprises two outer terminals and one central terminal. The outer terminals of the sound generator are electrically coupled to the output terminals of the control circuit. The central terminal of the sound generator is electrically coupled to the output of the voltage generation circuit.

The present invention is based on the finding that controlling a sound generator on the basis of a MEMS comprising an electrostatically controllable membrane generally requires electrical voltages that exceed the voltage level of conventional CMOS technology. Controlling such sound generators therefore requires a suitable control circuit which can provide electrical voltages at a sufficient voltage level. However, conventional control circuits can have a relatively high energy requirement.

It is therefore a concept of the present invention to take this finding into account and to provide efficient control for an electrostatic sound generator comprising a MEMS, which has a reduced energy requirement.

According to an example embodiment of the present invention, it is provided, on the one hand, to increase the electrical voltage level by means of a bias voltage through a voltage generator circuit. In addition, in analogy to a class H amplifier, the supply voltage for a differential amplifier provided in the control circuit can be adjusted on the basis of the current signal amplitude. This can take advantage of the fact that sound signals generally only very rarely have a high, in particular maximum, amplitude. During the generally relatively long phases of low signal amplitudes, the differential amplifier can however be operated with a lower supply voltage. This results in a significantly lower energy requirement. This can significantly increase the operating time per battery charge, in particular in battery-powered systems.

In principle, any suitable differential amplifier circuit in the form of discrete components or integrated circuits that is suitable for providing an amplified output signal corresponding to an input signal and that can be operated with a variable supply voltage can be used as a differential amplifier. As will be explained in more detail below, the differential amplifier can be operated with a supply voltage between a reference potential (0 volts) and a (positive) supply voltage or, in an alternative embodiment, with a negative and a positive supply voltage.

According to an example embodiment of the present invention, the output voltage provided at the two output terminals of the differential amplifier can be provided at the outer terminals of the electrostatic MEMS sound generator. Furthermore, an electrical voltage which is raised to a higher voltage level by means of the voltage generator circuit can be provided at a central terminal of this sound generator. This bias voltage can raise the electrical voltage at the central terminal of the sound transducer, in particular relative to the common mode voltage of the differential amplifier. As a result, sufficiently high electrical voltages suitable for the operation of electrostatic sound transducers are applied to the sound transducer. The electrical voltage provided by the voltage generator can in particular be an electrical voltage with a predetermined constant electrical DC voltage.

The sound signals emitted by the sound generator generally have the maximum possible amplitude only relatively rarely. It is therefore possible to operate the differential amplifier with a lower operating/supply voltage during periods in which the sound signal to be emitted has only a lower amplitude. This enables an efficient and energy-saving operation. In particular, the supply voltage for differential amplifiers can be adjusted on the basis of the current amplitude of the electrical signal. For example, the input signal can be continuously monitored or evaluated in order to ascertain a maximum amplitude within a specified time interval. The supply voltage of the differential amplifier can then be adjusted in each case according to the maximum amplitude ascertained for this time interval. For example, the supply voltage can be set to a voltage level that still allows a sufficient safety reserve for amplifying the input signal.

According to one example embodiment of the present invention, the control circuit comprises a level converter. The level converter can be designed to adjust a signal level of the input signal. Furthermore, the level converter can be designed to provide the adjusted input signal at the input terminals of the differential amplifier. In this way, it is possible to adjust the voltage range of the input signal to a voltage range that is suitable for the subsequent amplification by the differential amplifier. For example, an input signal with positive and negative voltage components can be converted by means of a corresponding level adjustment into a signal that no longer has any negative voltage component. Such a signal can then, for example, also be amplified by means of a differential amplifier, where the differential amplifier is operated between 0 V and a positive supply voltage.

According to one example embodiment of the present invention, the control circuit is designed to set a supply voltage for the level converter on the basis of a maximum amplitude of the input signal. In this way, analogously to the concept of the differential amplifier according to the present invention, the level converter can also be operated in each case with a supply voltage that, on the one hand, is sufficient to carry out the required level adjustment but, on the other hand, makes an efficient and energy-saving operation possible by temporarily lowering the supply voltage.

According to one example embodiment of the present invention, the control circuit is designed to provide an electrical voltage between a reference potential and a specified positive supply voltage as the supply voltage. In this way, it is sufficient to adjust only the positive supply voltage to the particular voltage level in each case.

According to one example embodiment of the present invention, the control circuit is designed to provide an electrical voltage between a specified negative supply voltage and a specified positive supply voltage as the supply voltage. Although both positive and negative supply voltages must each be dynamically adjusted in this case, this approach can make it possible to dispense with an adjustment of the supply voltage for the upstream level adjustment. Rather, the upstream level adjustment can be carried out with a constant supply voltage if negative voltages are also possible for the differential amplifier.

According to one example embodiment of the present invention, the control circuit comprises a signal processing device. The signal processing device is designed to receive a digital audio signal and to convert the digital audio signal into an analog audio signal. Furthermore, the signal processing device can provide the analog audio signal as an input signal to the level converter or the differential amplifier. In addition, the signal processing device is designed to ascertain the maximum amplitude of the input signal using the digital input signal. Since in this case the digital-to-analog conversion and the ascertainment of the maximum voltage amplitude can be carried out in parallel using the digital input signal, it is possible, due to the delay caused by the processing time of the digital-to-analog conversion, to provide the maximum amplitude of the input signal before the D/A conversion for the corresponding signal portion is completed. The corresponding supply voltage for the differential amplifier and, if applicable, the level converter can thus already be adjusted in a suitable manner when the analog signal is output by the D/A converter.

According to one example embodiment of the present invention, the signal processing device is designed to process the digital signal using a digital signal processor (DSP). This signal processed by the DSP can subsequently be converted into an analog audio signal. For this purpose, a D/A converter downstream of the DSP can usually be used. In particular, due to the processing-time delays that occur during the processing by the DSP, the maximum amplitude of the signal that is ascertained in parallel in the digital domain is thus available in good time for adjusting the supply voltage to the differential amplifier and, if applicable, the level converter.

The above example embodiments and developments can be combined with one another in any manner insofar as is reasonable. Further embodiments, developments, and implementations of the present invention also include combinations, even those not explicitly mentioned, of features of the present invention described above or in the following with regard to the exemplary embodiments. A person skilled in the art will in particular also add individual aspects as improvements or additions to the respective basic forms of the present invention.

### BRIEF DESCRIPTION OF THE DRAWINGS

Further features and advantages of the present invention will be explained in the following with reference to the figures.

FIG. 1 is a schematic representation of a principle circuit diagram for a sound generation system according to one example embodiment of the present invention.

FIG. 2 is a schematic representation of a principle circuit diagram of a control circuit for a sound generator according to one example embodiment of the present invention.

FIG. 3 is a schematic representation of a block diagram of an audio system for a sound generation system according to one example embodiment of the present invention.

FIG. 4 is a schematic representation of a principle circuit diagram of a control circuit for a sound generator according to a further example embodiment of the present invention.

### DETAILED DESCRIPTION OF EXAMPLE EMBODIMENTS

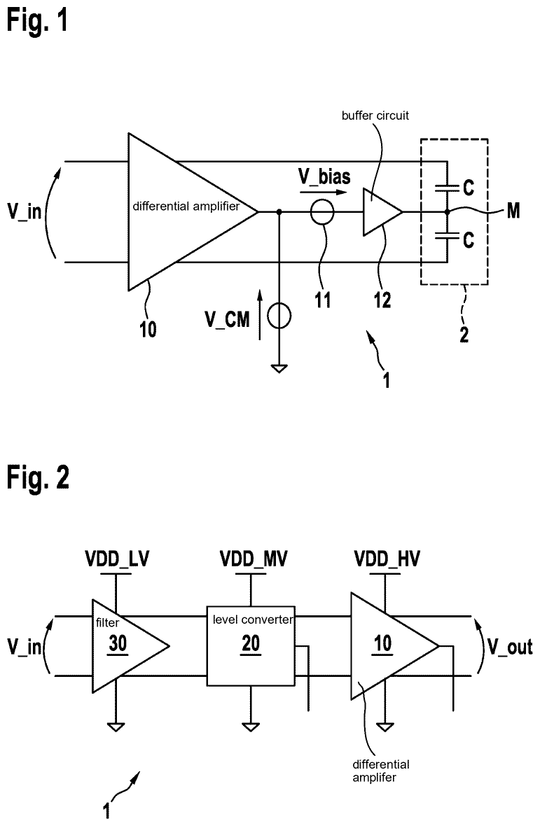

FIG. 1 shows a schematic representation of a principle circuit diagram for a sound generation system comprising a control circuit 1, according to one embodiment. The sound generation in this sound generation system takes place here by means of an electrostatic sound generator 2, in particular a sound generator 2 comprising a microelectromechanical system (MEMS). Here, a membrane of the sound generator 2 can be deflected by providing sufficiently high electrical voltages. In FIG. 1, this sound generator 2 is represented by the two capacitors C1 and C2, which are electrically connected to one another at a central terminal M. The other terminals of the capacitors C1 and C2 form the outer terminals of the sound generator 2.

In order to control the sound generator 2, an input signal V_in can be amplified by means of a differential amplifier 10. The two output terminals of the differential amplifier 10 can be electrically connected to the outer terminals of the sound transducer 2. In order to be able to provide a sufficiently high electrical voltage for the deflection of the membrane of the electrostatic sound generator 2, an electrical voltage raised by a bias voltage V_bias in comparison to the common mode voltage V_CM of the differential amplifier 10 is provided at the central terminal M of the sound generator 2. For this purpose, a voltage generator circuit 11 can be provided in the control circuit 1 comprising the differential amplifier 10. The thus increased common mode voltage can, if necessary, be fed to the central terminal M of the sound generator 2 via a buffer circuit 12.

The control circuit 1 must be dimensioned in such a way that the maximum expected amplitudes of the input signal V_in can also be amplified according to the posed requirements and with sufficient quality. In order to amplify signals with the maximum expected amplitude in the input signal V_in, a correspondingly high supply voltage must be provided at the differential amplifier 10.

FIG. 2 shows a schematic representation of a block diagram for a control circuit 1 for a sound generation system comprising an electrostatic MEMS sound generator 2, according to one embodiment. The (analog) input signal V_in can, for example, first be fed to a filter 30, in particular a low-pass filter, optionally with suitable buffering. This filter device 30 can be operated with a relatively low supply voltage VDD_LV. The output signal from these filter devices 30 can then be fed to a level converter 20. This level converter 20 can for example raise the signal, provided by the filter device 30, by a DC voltage component so that the output signal provided by the level converter 20 is suitable for being amplified in the corresponding voltage range by the downstream differential amplifier 10. The level converter 20 can be operated with a supply voltage VDD_MV, which is generally between the supply voltage VDD_LV of the filter device 30 and the supply voltage VDD_HV of the differential amplifier 10. For example, the voltage level of the input signal V_in can be raised to such an extent that the raised signal does not contain any signal components with a negative voltage, i.e., less than 0 volts.

The signal output by the level converter 20 is subsequently amplified by the differential amplifier 10 and fed to the sound generator 2 as already described in connection with FIG. 1.

The differential amplifier 10 and the level converter 20 must in principle be designed for the maximum expected amplitude of the input signal V_in. Accordingly, the input voltages of the differential amplifier 10 and of the level converter 20 must also be provided with sufficient safety reserves according to the amplitude of the input signal V_in.

However, since, especially in the case of sound signals, the maximum expected amplitude in the input signal V_in occurs only relatively rarely, it is also sufficient, for signal portions with a lower amplitude, to operate the differential amplifier 10 and, if applicable, the level converter 20 with a lower supply voltage during these signal portions. According to the present invention, it is therefore provided to adjust the supply voltage VDD_HV of the differential amplifier 10 and, if applicable, also the supply voltage VDD_MV of the level converter 20 according to the current amplitude of the input signal V_in and, in particular, to lower the supply voltage VDD_HV and, if applicable, VDD_MV in portions with a low amplitude in the input signal V_in.

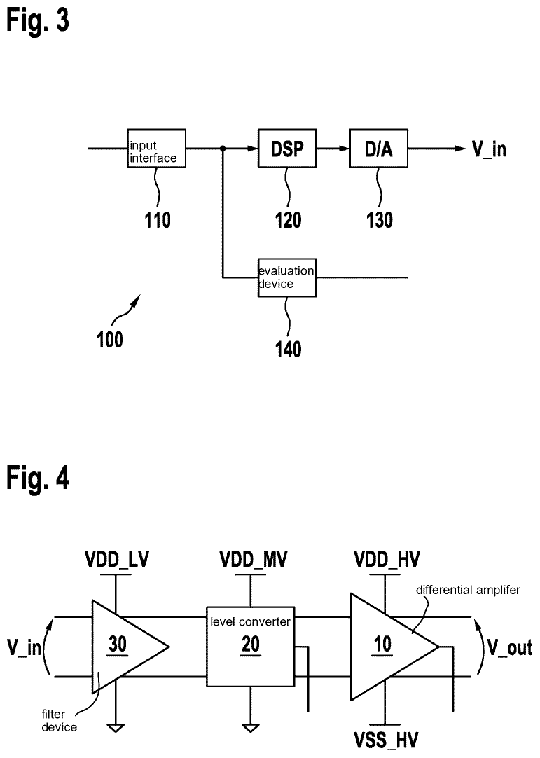

In order to adjust the supply voltages VDD_MV and VDD_HV to the particular signal amplitude in good time, the analysis of the input signal V_in can take place for example on the basis of a digital signal before this digital signal is converted into an analog input signal V_in. An exemplary approach in this respect is shown in FIG. 3, for example.

As can be seen in the arrangement according to FIG. 3, a digital signal can be received for example by means of a corresponding input interface 110. If necessary, the volume, i.e., the amplitude, can also be adjusted in the digital domain. The digital signal can then be processed, for example filtered or similar, in a first signal path, for example by means of a digital signal processor (DSP) 120. The processed digital signal can subsequently be converted into an analog signal V_in by means of a digital-to-analog converter (D/A) 130. In parallel, in a further signal path, a corresponding evaluation device 140 can ascertain a maximum amplitude of the current audio signal on the basis of the digital data. For example, the maximum amplitude over a specified time period can be ascertained for this purpose. In principle, however, any other approaches to ascertaining a current maximum amplitude in the digital data are also possible.

Since the processing of the digital signal in the DSP 120 and the downstream D/A converter 130 can result in a processing-time delay that is greater than the time required to ascertain the current maximum amplitude in the device 140, the supply voltage VDD_HV for the differential amplifier 10 and, if applicable, the level converter 20 can each be adjusted in good time to the signal curve of the (analog) input signal V_in on the basis of this ascertainment of the maximum amplitude.

FIG. 4 shows a schematic representation of a block diagram for a control circuit 1 for a sound generation system comprising an electrostatic MEMS sound generator 2, according to a further embodiment. The control circuit 1 in this embodiment differs from the above-described control circuit 1 according to FIG. 2 in particular in that the differential amplifier 10 is operated with a supply voltage not between a reference potential (0 volts) and a positive supply voltage VDD_HV but between a negative supply voltage VSS_HV and a positive supply voltage VDD_HV. These supply voltages VSS_HV and VDD_HV can be adjusted analogously to the above-described concept according to the current signal amplitude in the input signal V_in.

Due to the possibility that in this case a negative supply voltage can also be provided to the differential amplifier and the output signal can thus also extend into the negative range, the signal no longer has to be raised as much by the level converter 20, in particular in the case of input signals V_in with larger amplitudes. The level converter 20 can thus be operated continuously with a constant supply voltage VDD_MV. An adjustment of the supply voltage for the level converter 20 can thus be omitted.

In addition, the above statements apply in particular also to the ascertainment of the current amplitude in the digital input signal with adjustment of the supply voltages VSS_HV and VDD_HV.

In summary, the present invention relates to the control of an electrostatic sound transducer comprising a microelectronic component. For this purpose, a control circuit comprising a differential amplifier is provided, wherein, at a central terminal of the sound transducer, a bias voltage is provided relative to the common mode voltage of the differential amplifier. The supply voltage of the differential amplifier can be adjusted on the basis of the signal amplitude of the input signal.

1-9. (canceled)

10. A control circuit for a microelectromechanical sound generator including two outer terminals and one central terminal, the control circuit comprising:
a differential amplifier which includes two output terminals electrically coupled to the two outer terminals of the sound generator and is configured to provide, between the two output terminals, an output voltage that corresponds to an input signal between two input terminals of the differential amplifier; and
a voltage generator circuit configured to provide, at the central terminal of the sound generator, a predetermined DC voltage relative to a common mode voltage of the differential amplifier;
wherein the control circuit is configured to set a supply voltage for the differential amplifier based on a maximum amplitude of the input signal.

11. The control circuit according to claim 10, further comprising a level converter configured to adjust a signal level of the input signal and to provide the adjusted input signal at the input terminals of the differential amplifier.

12. The control circuit according to claim 11, wherein the control circuit is configured to set a supply voltage for the level converter based on the maximum amplitude of the input signal.

13. The control circuit according to claim 11, wherein the control circuit is configured to provide, as the supply voltage for the differential amplifier, an electrical voltage between a reference potential and a specified positive supply voltage.

14. The control circuit according to claim 9, wherein the control circuit is configured to provide, as the supply voltage for the differential amplifier, an electrical voltage between a specified negative supply voltage and a specified positive supply voltage.

15. The control circuit according to claim 9, further comprising a signal processing device configured to receive a digital audio signal, to convert the digital audio signal into an analog audio signal, and to provide the analog audio signal as the input signal to the level converter or the differential amplifier, wherein the signal processing device is further configured to ascertain the maximum amplitude of the input signal using the digital input signal.

16. The control circuit according to claim 15, wherein the signal processing device is configured to process the digital signal using a digital signal processor and subsequently to convert the processed digital signal into an analog audio signal.

17. A sound generation system, comprising:
a microelectromechanical sound generator; and
a control circuit;
wherein the microelectron mechanical sound generator includes two outer terminals and one central terminal;
wherein the control circuit includes:
a differential amplifier which includes two output terminals electrically coupled to the two outer terminals of the sound generator and is configured to provide, between the two output terminals, an output voltage that corresponds to an input signal between two input terminals of the differential amplifier, and
a voltage generator circuit configured to provide, at the central terminal of the sound generator, a predetermined DC voltage relative to a common mode voltage of the differential amplifier,
wherein the control circuit is configured to set a supply voltage for the differential amplifier based on a maximum amplitude of the input signal.

18. The sound generation system according to claim 17, wherein the sound generator includes a microelectromechanical system which includes an electrostatically controlled membrane.
